(19) United States
(12) Patent Application Publication
(10) Pub. No.: US 2026/0085716 A1
(43) Pub. Date: Mar. 26, 2026

(54) MOUNTING HOLDER FOR FASTENERS

(71) Applicant: DANA TM4 ITALIA S.R.L., Arzignano (IT)

(72) Inventors: Mirko SGAGGIO, Vestenanova (IT); Walter FAEDO, Vestenanova (IT); Enrico DAL MORO, Lonigo (IT)

(21) Appl. No.: 18/895,806

(22) Filed: Sep. 25, 2024

(51) Int. Cl. F16B 41/00; H05K 1/02

(52) U.S. Cl. CPC F16B 41/002; H05K 1/02; F16B 2200/93; H05K 2201/1031

(57) ABSTRACT

Systems and methods are disclosed for fastening systems used to fasten components to a printed circuit board (PCB). The fastening system includes a mounting holder and a fastener held within a metal case of the mounting holder by a retaining washer prior to fastening. The metal case is soldered or welded to the PCB to pre-position the fastener prior to fastening. The metal case guides a fastening tool used to fasten the fastener.

### TECHNICAL FIELD

The present description relates generally to mounting holders for fastening of fasteners during assembly of printed circuit boards and other components.

### BACKGROUND AND SUMMARY

Printed circuit boards (PCBs) are used in electrical systems such as power converters, inverters, electric drives, etc. In some systems, two PCBs may be fixed in parallel at a distance from each other by fasteners (e.g., screws) with spacers interposed between the two PCBs. Conventionally, assembly of such a system of two PCBs may be performed manually, including positioning and tightening of the screws to attach the spacers to the two PCBs, as part of a manual assembly line. If a screw is misaligned (e.g., offset from a corresponding threaded hole) in manual positioning, the screws and/or tools (e.g., screwdriver) may fall or slip upon application of pressure to the screw head, potentially causing degradation to the system or loss of screws. In this way, manual positioning may be delicate due to the small size of the screws, and may add time to the assembly process. Further, manual installation may include selection of the screws from different types, potentially leading to exchanging types of screws and unsuitable screws being installed, decreasing structural integrity of the system. Further still, manual assembly may include aligning the PCBs relative to each other, potentially allowing for errors in relative orientations of the PCBs such as inversion of the system. For example, a surface intended to face inwards (e.g., towards the other PCB) may be installed facing outwards if the PCB coupling directions are misidentified.

Thus, embodiments of a fastening system that address at least some of the issues described above are disclosed herein. The fastening system comprises a fastener, and a metal case surrounding the fastener and adapted to be soldered to a PCB, where a top of the metal case has an opening adapted to permit a fastening tool to drive the fastener down. The fastening system further comprises a retaining washer adapted to retain the fastener within the metal case prior to an application of the fastening tool, and a destructible film positioned on the top of the metal case. A mounting holder, including the retaining washer and the metal case, may be mounted automatically onto the PCB, for example with the same machines used for the production of the PCB. Using the fastening system, the fastener may be automatically centered prior to fastening, and guided to remain in alignment with corresponding holes during fastening. Automatic positioning of the fastener via assembly machines may remove the fastener from the manual assembly line, reducing assembly time, manual errors, and manual steps. For example, pre-loading of mechanical components on the PCB may eliminate manual exchange of fastener types for unsuitable fasteners. Pre-positioned fasteners may also allow for easier identification of PCB coupling directions, reducing instances of inverted installation or other errors in relative orientations of the PCB. Additionally, the metal case guiding the fastening tool during fastening may protect against fastening tool errors, increasing speed of fastening, and reducing slips under pressure on a fastener head or other errors that may cause degradation to parts of the system. Further, the destructible film (e.g., layer of paper material) may serve as a visual confirmation that the fastener has been fastened, reducing instances of installers not fastening all of the fasteners. Moreover, in examples where the metal case is coated in an electrically insulating material, the metal case may insulate the fasteners from live components.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE FIGURES

FIG. 1 shows a system comprising a printed circuit board (PCB) secured to a component via a fastening system in accordance with the present disclosure.

FIGS. 2A and 2B show an example of the fastening system in accordance with the present disclosure in a perspective view and a side view, respectively.

FIGS. 3A and 3B show an example of the fastening system in accordance with the present disclosure in a perspective view and a cross-section view, respectively.

FIG. 4 shows a flowchart of a method in accordance with the present disclosure for assembling a PCB system such as the system of FIG. 1 with fastening systems.

FIGS. 5A-5D show views of a fastening system at different steps of assembly.

FIGS. 6A-6D show views of a fastening system at different steps of assembly.

FIG. 7 shows a fastening system in an unfastened state.

FIG. 8 shows destructible films of fastening systems in an unfastened state and a fastened state.

### DETAILED DESCRIPTION

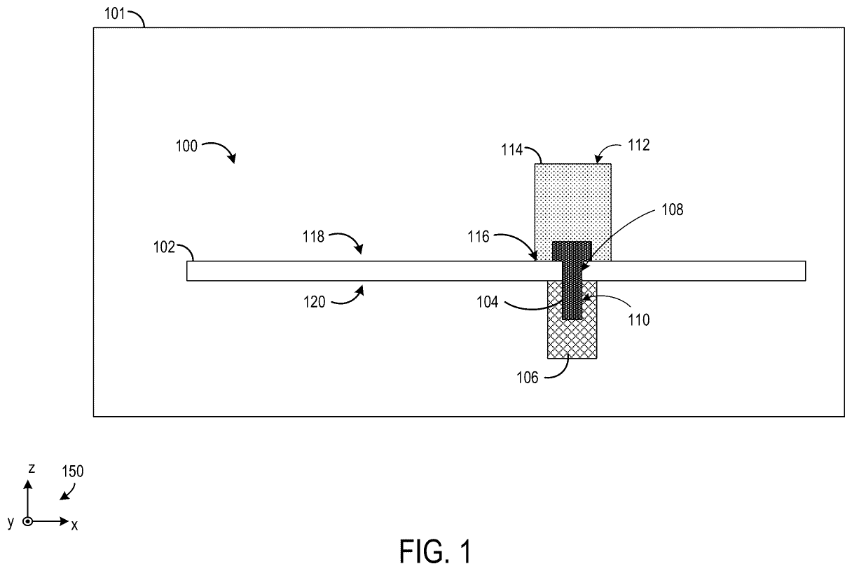

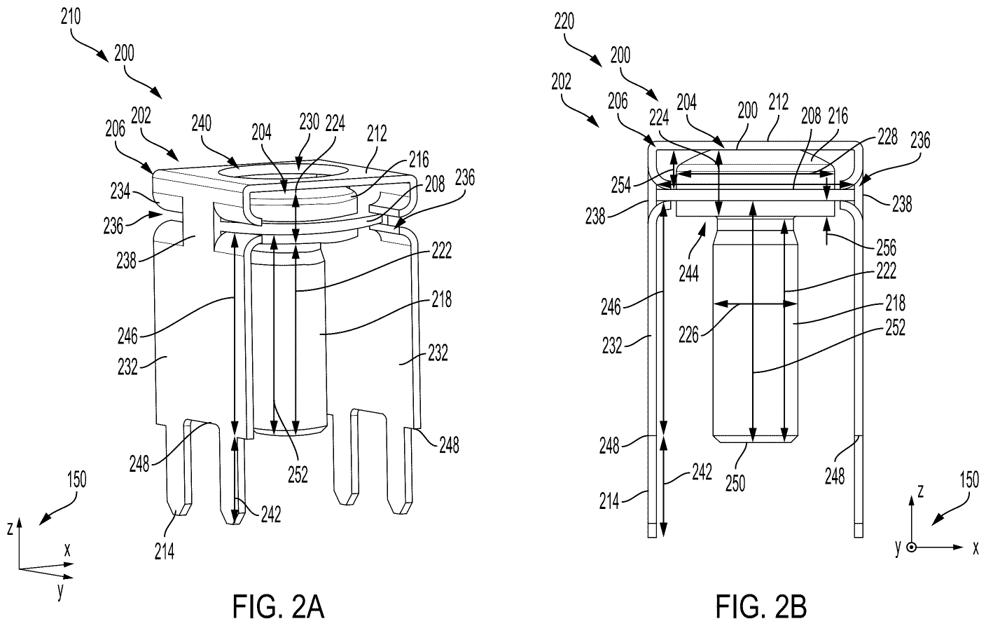

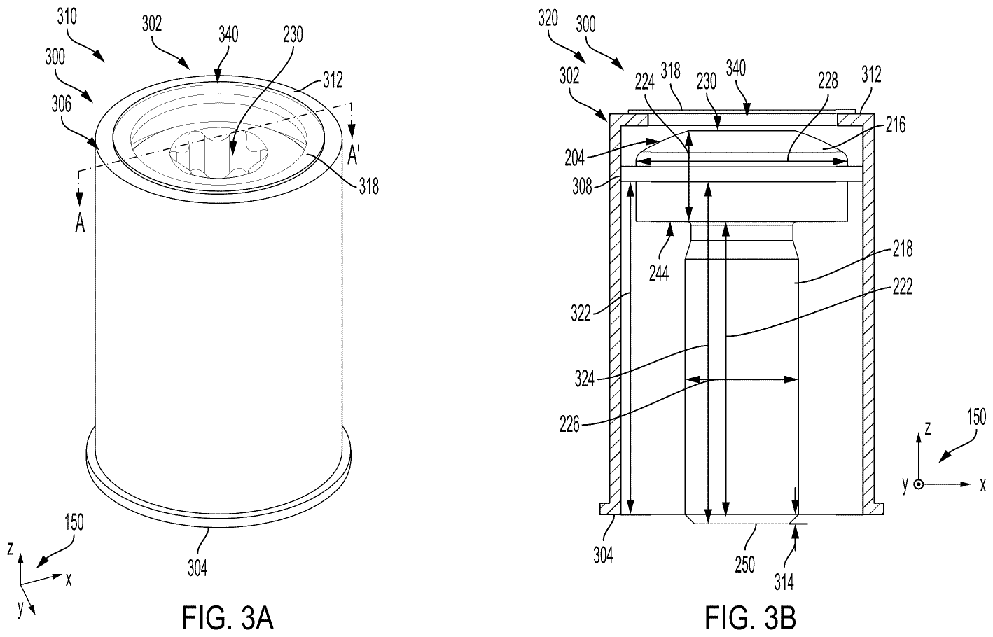

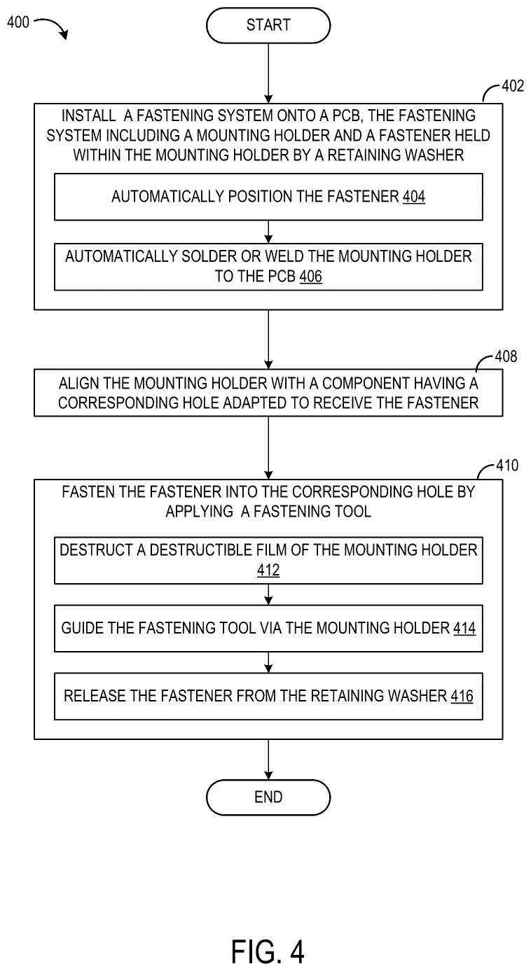

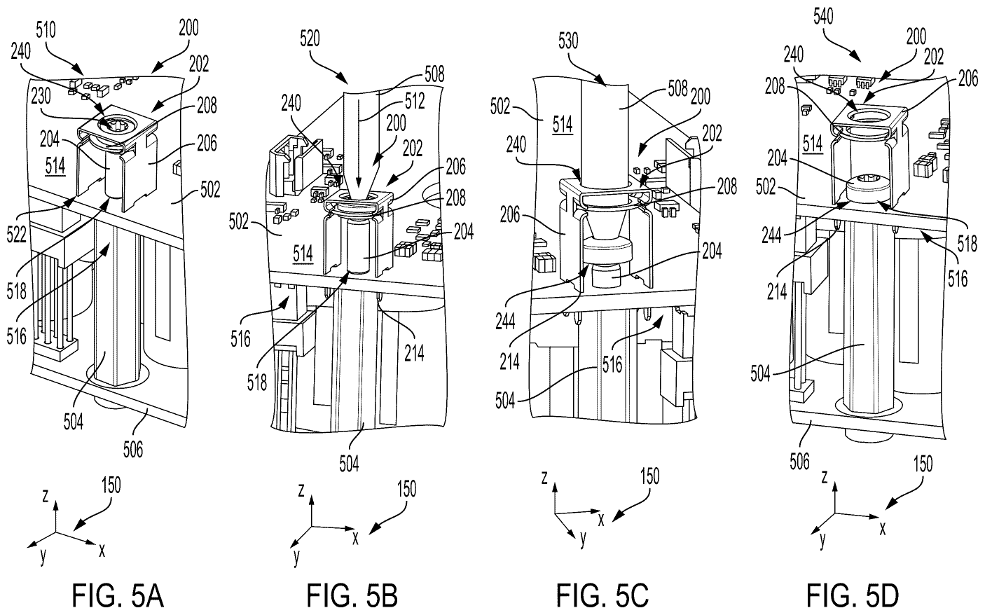

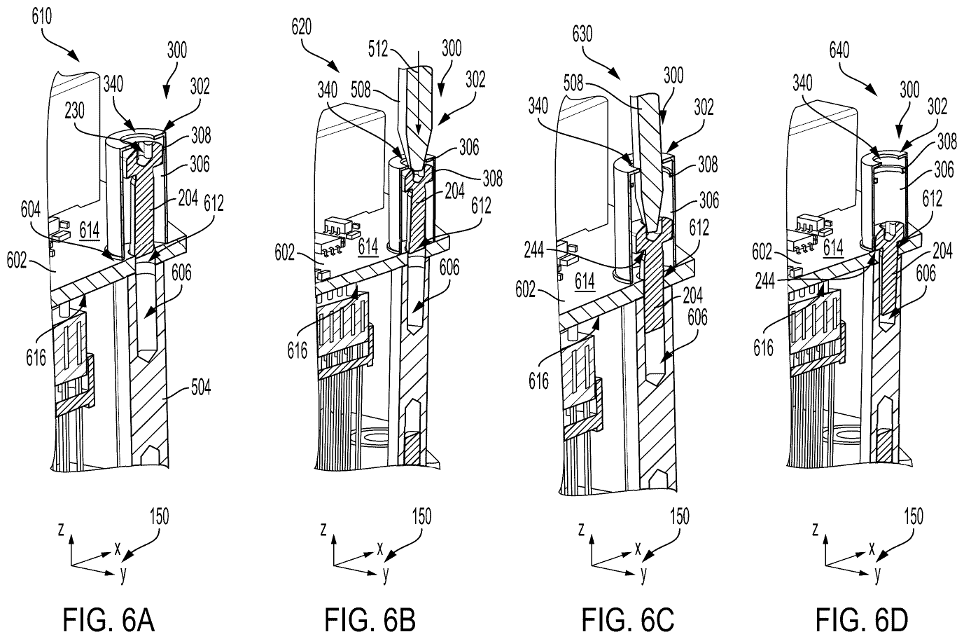

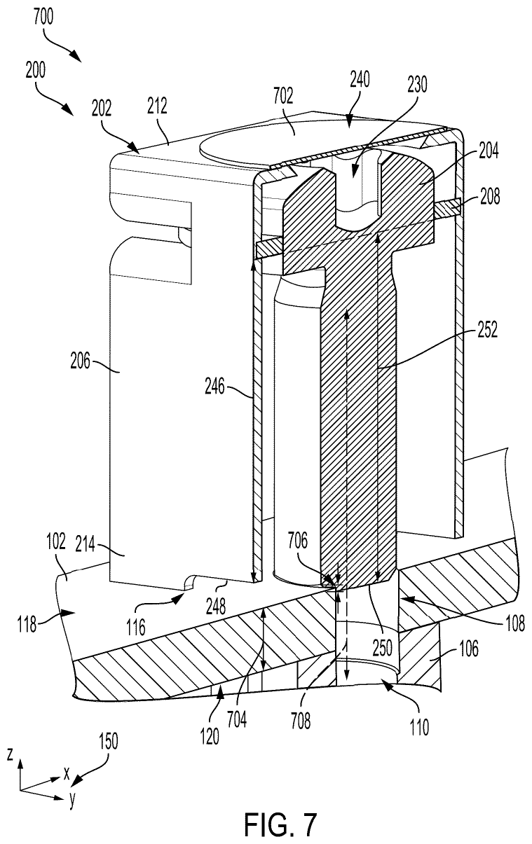

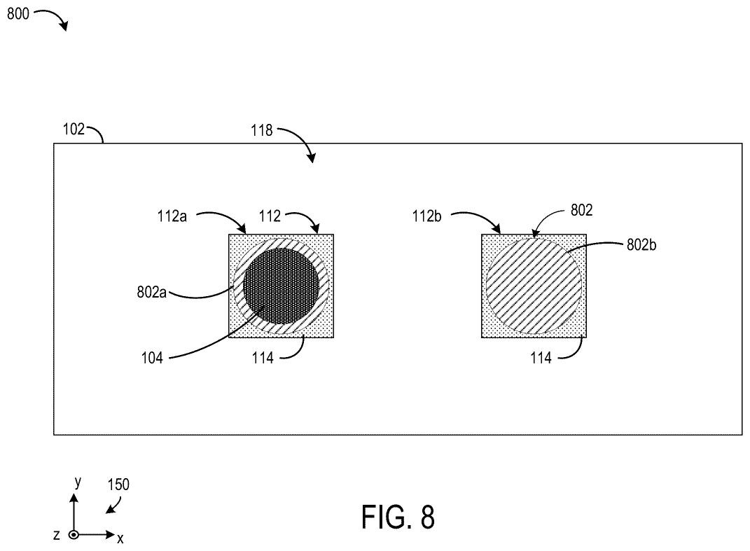

The following description relates to systems and methods for mounting holders for aligning and guiding fasteners. A fastening system in accordance with the present disclosure may include a mounting holder and a fastener. The fastening system may be used to mechanically couple a component to a printed circuit board (PCB). In the method of the present disclosure for assembling a system with fastening systems, the mounting holder encompassing the fastener may be automatically installed onto the PCB during manufacture of the PCB such that the fasteners are pre-positioned without manual intervention. Subsequently, the fasteners may be driven automatically or manually by a fastening tool to insert the fastener through the PCB and a corresponding hole in a component to mechanically couple the component to the PCB. An exemplary method is shown as a flowchart in FIG. 4. An example of a system is shown in FIG. 1, where a fastener of a fastening system in accordance with the present disclosure mechanically couples a component (e.g., spacer) to a PCB. Examples of fastening systems in accordance with the present disclosure are shown in FIGS. 2A-3B. The examples of fastening systems are shown in different states of fastening, including unfastened and fastened states, in FIGS. 5A-6D. The fastening systems may be pre-positioned in the unfastened state with the fastener partially in a through-hole of the PCB, as shown in FIG. 7. Fastened fastening systems may include the fastener extending through the PCB and into the component such that the component and the PCB are mechanically coupled via the fastener. Unfastened fastening systems may include the fastener spaced away from the component such that the component is not coupled to the PCB. The fasteners, and fastening tools used to drive the fasteners, may be guided by the mounting holder during fastening. In this way, manual errors may be reduced, as well as assembly time. The fastening systems may include destructible films that are destructed upon application of the fastening tool. Thus, the destructible films may indicate whether the fasteners have been fastened, as shown in FIG. 8.

It is to be understood that the specific assemblies and systems illustrated in the attached drawings, and described in the following specification are exemplary embodiments of the inventive concepts defined herein. For purposes of discussion, the drawings are described collectively. Thus, like elements may be commonly referred to herein with like reference numerals and may not be re-introduced.

Turning to FIG. 1, a PCB system 100 comprising a PCB 102 coupled to a component 106 via a fastener 104 is shown. A set of reference axes 150, including an x-axis, a y-axis, and a z-axis, are provided in FIG. 1, as well as FIGS. 2A-3B and 5A-8. The x-axis and the y-axis may be lateral axes parallel with the PCBs, and the z-axis may be a vertical axis perpendicular to surfaces of the PCBs where components are mounted. The z-axis may be parallel with the fastener 104. However, other orientations are possible.

Though not shown in FIG. 1, a plurality of electrical components may be mechanically and electrically coupled (e.g., soldered) to the PCB 102, including any suitable electrical components according to an application of the PCB system 100, for example incorporation in an electrical system 101, such as an inverter, electric machine, or other electrical system of a vehicle (e.g., hybrid or electric vehicle).

The fastener 104 may mechanically couple the component 106 to the PCB 102. The fastener 104 may include any fastener type which may be fastened by application of a fastening tool to drive the fastener 104 into place, including a screw, rivet, bolt, etc. The fastener 104 may be removable from the component 106 in at least some examples. For examples where the fastener 104 is a screw, a screwdriver may be used to reversibly couple and decouple the fastener 104 and the component 106. In other examples, the fastener 104 may be permanently coupled to the component 106. For example, the fastener 104 may be a rivet such that the fastener 104 is permanently installed.

The component 106 may be any part of an assembly demanding secure attachment to the PCB 102. For example, the component 106 may be structural component. For example, the component 106 may be spacer adapted to couple with a second PCB such that the PCB 102 and the second PCB are secured (e.g., mechanically coupled) at a fixed distance from each other, as described further below. In such an example, the second PCB may be included in the PCB system 100, and incorporated into the electrical system 101.

The fastener 104 may extend through a through-hole 108 in the PCB 102. The through-hole 108 may be plated or non-plated. The through-hole 108 may be threaded according to the fastener 104. For examples where the fastener 104 includes threading, the through-hole 108 may include complementary threading. The fastener 104 may further extend into a corresponding hole 110 in the component 106. The corresponding hole 110 may be a blind hole or a through-hole such that the fastener 104 may extend at least partially through the component 106. The corresponding hole 110 may be shaped according to the fastener 104. For example, similar to the through-hole 108, the corresponding hole 110 may be threaded according to whether or not the fastener 104 is threaded. For examples where the fastener 104 is a screw, the corresponding hole 110 may be threaded complementarily to the threaded portion of the screw. By extending through the PCB 102 and at least partially through the component 106, the fastener 104 may secure the component 106 to the PCB 102.

In other examples, rather than a PCB such as the PCB 102, the fastener 104 may couple the component 106 to a metal plate, for instance, or another part able to be soldered or welded and having a through-hole similar to the through-hole 108 that is adapted to receive the fastener 104.

Conventionally, such a system as the PCB system 100 may be assembled manually, demanding manual positioning of the fastener 104 in alignment with through-hole 108 and corresponding hole 110 in the PCB 102 and the component 106, respectively. Additionally, manual fastening (e.g., screwing, pushing, tightening, etc.) of the fasteners may be demanded. Such an assembly method may result in slippage of the fasteners or fastening tool upon fastening, degrading parts of the system and increasing assembly time.

Thus, fastening systems and methods are disclosed herein for automatically pre-positioning and guiding the fasteners with mounting holders. For example, as shown in FIG. 1, a fastening system 112 includes the fastener 104 and a mounting holder 114 adapted to pre-position the fastener 104 prior to fastening (e.g., inserting the fastener 104 into the corresponding hole 110 to secure the component 106 to the PCB 102). For example, the mounting holder 114 may be aligned and either soldered or welded to the PCB 102 at an interface 116 therebetween by an automated machine, thereby removing demand for manual positioning of the fastener 104 prior to fastening. The mounting holder 114 may be positioned on a first side 118 of the PCB 102 and the component may be located on a second side 120 of the PCB 102, where the first side 118 faces oppositely from the second side 120. In this way, during fastening, the mounting holder 114 may indicate intended positioning of the component 106, reducing instances of assembly inversion (e.g., coupling the component 106 to the first side 118). Further, the mounting holder 114 may guide the fastener 104, as well as a fastening tool used to fasten the fastener 104 (e.g., screwdriver for tightening a screw), during fastening to avoid slipping during fastening. Additionally, reducing manual steps of an assembly line by automatically pre-positioning the fastener 104 may reduce other manually associated errors, such as interchanging fastener types for unsuitable fasteners. The fastening systems in accordance with the present disclosure are described further below in regard to FIGS. 2-8

Turning to FIGS. 2A and 2B, an example of a fastening system 200 in accordance with the present disclosure is shown in a perspective view 210 and a side view 220, respectively. The fastening system 200 includes a mounting holder 202 and a fastener 204. The fastening system 200 may be an example of the fastening system 112 of FIG. 1. Accordingly, the fastener 204 may be an example of the fastener 104 of FIG. 1 and the mounting holder 202 may be an example of the mounting holder 114 of FIG. 1. Specifically, the mounting holder 202 is an example of a plating through-hole (PTH) mounting holder configured to be inserted into through-holes in a PCB (e.g., PCB 102 of FIG. 1) for soldering or welding via PTH technology. The fastening system 200 may be utilized to secure a component (e.g., component 106) to the PCB via the fastener 204.

The fastener 204 may include a head 216 and a body 218, the body 218 being longer and narrower than the head 216. For example, a body length 222 of the body 218 may be longer than a head length 224 of the head 216. A body diameter 226 of the body 218 may be smaller than a head diameter 228 of the head 216. The fastener 204 may include a fastening tool receptacle 230 adapted to receive a fastening tool. For examples where the fastener 204 is a screw, the fastening tool receptacle 230 may be a cavity shaped complementarily to a tip of a screwdriver.

The mounting holder 202 may include a metal case 206 surrounding the fastener 204, and a retaining washer 208 that retains the fastener 204 prior to fastening. The fastening system 200 is shown in FIGS. 2A-2B in an unfastened state, where the fastener 204 is held in place by the retaining washer 208. In the unfastened state, the fastener 204 may be in face sharing contact with a top 212 of the metal case 206. Alternatively, the fastener 204 may be spaced away from the top 212, but in closer proximity to the top 212 than when the fastener 204 is in the fastened state of the fastening system 200 where the fastener 204 secures a component to a PCB. The fastening system 200 may be in the unfastened state prior to application of a fastening tool to drive the fastener 204.

The metal case 206 may be constructed at least partially of tin, copper, zinc, gold, silver, brass, antimony, indium, aluminum, bronze, a combination thereof, or other material suitable for welding or soldering such that the metal case 206 is adapted to be welded or soldered to a PCB (e.g., PCB 102 of FIG. 1). Specifically, leads 214 of the metal case 206 may be inserted into through-holes in the PCB and soldered thereto. The leads 214 may extend downwards (e.g., in the negative z-direction) from sides 232 of the metal case 206 with a length 242. The length 242 may be selected according to a thickness of the PCB such that the leads 214 extend fully therethrough. Parts of the metal case 206 (e.g., other than the leads 214) may be covered in an electrically insulating material (e.g., rubber, plastic, etc.) to increase electrical insulation between live electrical components and the fastener 204.

The sides 232 may be parallel with each other and located opposite across the fastener 204. In some other examples, there may be three or more sides, or a single cylindrical siding, such that the fastener 204 is circumferentially surrounded by the metal case 206, rather than interposed between two sides 232 as shown in FIGS. 2A and 2B. The sides 232 may be connected to the top 212 such that the metal case 206 is a single integrally formed piece, including the top 212, the sides 232, and the leads 214.

The top 212 may include an opening 240 adapted to permit and guide the fastening tool. For example, during fastening, the fastening tool may extend through the opening 240 to fasten the fastener 204 with the component, as described further below in regard to FIGS. 4-5D. As such, the opening 240 may be shaped and sized according to the fastening tool and the fastener 204. For example, the opening 240 may have a greater diameter than the fastening tool to permit the fastening tool to enter the metal case 206 during fastening. Additionally or alternatively, the opening 240 may have a smaller diameter than the head 216.

The retaining washer 208 may be secured to the metal case 206. For example, the metal case 206 may include indents 234 that bend inward towards the fastener 204 to form slots 236 that hold the retaining washer 208. In this way, the retaining washer 208 may be embedded in the metal case 206. Alternatively, the retaining washer 208 may be co-molded with the metal case 206 as described with regard to FIGS. 3A and 3B. In examples where the retaining washer 208 is embedded into the metal case 206 via the slots 236, there may be connectors 238 extending between the slots 236, where the connectors 238 are unbent portions of the sides 232.

The retaining washer 208 may hold the fastener 204 within the metal case 206 prior to application of a fastening tool to fasten the fastener 204. The slots 236 may be spaced away from the top 212 such that the retaining washer 208 embedded in the slots 236 may be spaced away from the top 212. Specifically, the retaining washer 208 may be spaced away from the top 212 by a distance 254, where the distance 254 is smaller than the head length 224. Thus, the retaining washer 208 may also be spaced away from a head bottom 244 of the head 216 by a distance 256, where the head bottom 244 abuts the PCB when fastened. In this way, the retaining washer 208 may circumferentially surround the head 216 when the fastener 204 is in the unfastened state. The retaining washer 208 may be constructed of rubber or other flexible material suitable for holding the fastener 204 in place within the mounting holder 202 prior to application of force to the fastener 204 during fastening. For example, friction between the retaining washer 208 and the fastener 204 may retain the fastener 204 in place (e.g., in face sharing contact with or near the top 212) prior to application of the fastening tool.

In the unfastened state, the fastener 204 may extend slightly beyond the sides 232 in the z-axis direction. For example, a distance 252 from the retaining washer 208 to an end 250 of the fastener 204 (e.g., sum of the distance 256 and the body length 222) may be greater than a distance 246 between the retaining washer 208 and the leads 214. In this way, bottom edges 248 of the sides 232 from which the leads 214 extend may rest upon the PCB when soldered or welded thereto, allowing the fastener 204 to extend partially into the through-hole in the PCB. Thus, the fastener 204 may be pre-positioned in alignment with the through-hole in the PCB prior to fastening by application of the fastening tool.

For example, turning to FIG. 7, a cross section view 700 is shown of the fastening system 200 soldered to the PCB 102 and in the unfastened state. For example, the view 700 may show the fastening system 200 following installation onto the PCB 102 and prior to application of a fastening tool for fastening.

As described above with regard to FIG. 1, the mounting holder 202 may be soldered or welded to the first side 118 of the PCB 102, manually or automatically. The mounting holder 202 may be aligned with the through-hole 108 such that the fastener 204 extends partially into the through-hole 108, by a distance 706. The distance 706 may be a difference between the distance 252 and the distance 246. The distance 706 may be a non-zero distance less than a thickness 704 of the PCB 102. In this way, the fastener 204 may extend partially into the PCB 102 to ensure alignment of the fastener 204 with the through-hole 108 during fastening.

The component 106 may be positioned on a second side 120 of the PCB 102, where the second side 120 is opposite the first side 118 (e.g., facing opposite directions). Further, the component 106 may be aligned with the through-hole 108 and the fastener 204. For example, centers of the fastener 204, the through-hole 108, and the corresponding hole 110 may be coaxially located along a central axis 708 that is perpendicular to the PCB 102. In the unfastened state of the fastening system 200, the component 106 may not be mechanically coupled to the PCB 102 or the fastener 204. Upon application of a fastening tool, the fastener 204 may be driven through the through-hole 108 and into the corresponding hole 110, securing the PCB 102 and the component 106.

Further, a destructible film 702 may span at least part of the top 212 to at least partially cover opening 240. The destructible film 702 may be sized and shaped according to the opening 240. For example, the destructible film 702 may be circular in shape with larger diameter than the opening 240 such that the destructible film 702 overlaps the opening 240 and parts of the top 212. The destructible film 702 may be attached to the top 212, for example via adhesive. The destructible film 702 may be constructed of a paper material, or other material that is destructible by application of pressure, for example with the fastening tool. Further, the destructible film 702 may be brightly colored to draw attention during visual inspection to whether the film is intact or broken. In this way, the fastening tool may break the destructible film 702 upon application, providing visual confirmation that fastening has occurred. The destructible film 702 is an example of a flat destructible film. An example of a conforming destructible film is described below in regard to FIGS. 3A and 3B, where the conforming destructible film is modified according to geometry of the fastener 104 and metal case to include indents into the fastening tool receptacle 230 and other bends, rather than being a flat, planar film similar to the destructible film 702.

Turning to FIGS. 3A and 3B, another example of a fastening system 300 in accordance with the present disclosure is shown in a perspective view 310 and a cross section view 320, respectively. The cross section view 320 is a section taken along segment A-A′ in FIG. 3A. The fastening system 300 includes a mounting holder 302. The fastening system 300 includes the fastener 204 described with regard to fastening system 200 of FIGS. 2A and 2B. In this way, the mounting holder 302 and the mounting holder 202 of FIGS. 2A and 2B, which are both examples of the mounting holder 114 of FIG. 1, may both be configured to hold the same fastener. The fastening system 300 may be an example of the fastening system 112 of FIG. 1. Specifically, the mounting holder 302 is an example of a surface-mounted device (SMD) mounting holder configured to be mounted to the surface of a PCB (e.g., PCB 102 of FIG. 1) for soldering or welding via SMD technology, rather than PTH. The fastening system 300 may be utilized to secure a component (e.g., component 106 of FIG. 1) to the PCB via the fastener 204.

The mounting holder 302 may include a metal case 306 surrounding the fastener 204, and a retaining washer 308 that retains the fastener 204 prior to fastening. The fastening system 300 is shown in FIGS. 3A-3B in an unfastened state, where the fastener 204 is held in place by the retaining washer 308. In the unfastened state, the fastener 204 may be in face sharing contact with a top 312 of the metal case 306. Alternatively, the fastener 204 may be spaced away from the top 312, but in closer proximity than in the fastened state of the fastening system 300 where the fastener 204 secures a component to a PCB (e.g., the component 106 to the PCB 102 as shown in FIG. 1). The fastening system 300 may be in the unfastened state prior to application of a fastening tool to drive the fastener 204 downwards relative to the mounting holder 302.

The metal case 306 may be cylindrical shaped and flat on bottom edge 304 so as to be welded or soldered to a PCB as an SMD. Unlike the metal case 206, the metal case 306 may not protrude through the PCB. In other examples, the metal case 306 may comprise three or more sides encircling the fastener 204, rather than a cylinder. The metal case 306 may include an opening 340 through which a fastening tool may access the fastener 204. Like the opening 240 of the metal case 206 of FIGS. 2A and 2B, the opening 340 may be sized and shaped to permit the fastening tool. For example, the opening 340 may be larger than the fastening tool such that the fastening tool may extend through the opening 340 during fastening. Additionally, the opening 340 may guide the fastening tool to maintain alignment with the fastener 204 and perpendicularity with the PCB, reducing degradation of the fastener and PCB during fastening due to slipping, falling, etc. For example, edges defining the opening 340 may be in face sharing contact with the fastener during fastening.

Like the metal case 206 of FIGS. 2A and 2B, the metal case 306 may be constructed at least partially of tin, copper, zinc, gold, silver, brass, antimony, indium, aluminum, bronze, a combination thereof, or other material suitable for welding or soldering such that the metal case 306 is adapted to be welded or soldered to a PCB (e.g., PCB 102 of FIG. 1). Specifically, a bottom edge 304 of the metal case 306 may be soldered or welded to the surface of the PCB via SMD technology. Parts of the metal case 306 (e.g., other than the bottom edge 304) may be covered in an electrically insulating material (e.g., rubber, plastic, etc.) to increase electrical insulation between electrical components and the fastener. For example, a coating of electrically insulating material may be applied in an even layer over surfaces of the metal case 306 (or the metal case 206) other than soldering or welding interface surfaces (e.g., interface 116 of FIG. 1).

The retaining washer 308 may be co-molded with the metal case 306, rather than embedded as described above with respect to FIGS. 2A-2B. In this way, the retaining washer 308 may be mechanically fixed to the metal case 306 via a bond between the materials. The retaining washer 308 may be substantially the same as the retaining washer 208 of FIGS. 2A and 2B. As such, the retaining washer 308 may be a rubber or other flexible material circumferentially surrounding the head 216 such that the retaining washer 308 fixes the fastener 204 in place relative to the metal case 306 in the unfastened state, prior to application of the fastening tool.

In the unfastened state of the fastening system 300, a distance 322 between the retaining washer 308 and the bottom edge 304 may be shorter than a distance 324 between the retaining washer 308 and the bottom end 250 of the fastener 204. In this way, the fastener 204 may protrude out of the metal case 306 by a distance 314 such that when the metal case 306 is positioned on a surface of the PCB, the fastener 204 may extend partially into a through-hole of the PCB (e.g., through-hole 108 of FIG. 1) by the distance 314. For example, the distance 314 may be approximately the same as the distance 706 of FIG. 7 by which the fastener 204 protrudes into the PCB 102 in the unfastened state of the fastening system 200. In this way, as described above, the fastener 204 may be pre-positioned in alignment with a through-hole in the PCB (e.g., through-hole 108) during welding or soldering of the mounting holder 302 to the PCB. Thus, manual positioning of the fastener 204 may not be demanded, reducing assembly time.

The mounting holder 302 may also include a destructible film 318. The destructible film 318 may conform to a surface of the fastener 204, rather than being flat similar to the destructible film 702 of FIG. 7. For example, the destructible film 318 may take the shape of the fastening tool receptacle 230. In this way, the destructible film 318 may form a coating of approximately even layer over the fastener 204 and at least part of top 312 of the metal case 306. The destructible film 318 may be broken upon application of the fastening tool during fastening of the fastener 204. Thus, the destructible film 318 may provide an optical difference indicating the fastener 204 being unfastened or fastened. In this way, the state of the fastening system 300 (e.g., fastened or unfastened) may be determined without inspecting positioning of the fastener 204 directly. In other examples, the destructible film 318 may be flat as described with regard to FIG. 7.

Turning to FIG. 8, examples of intact and destructed destructible films 802 (e.g., destructible film 702 of FIG. 7 or destructible film 318 of FIGS. 3A and 3B) are shown schematically in a top-down view 800 of the first side 118 of the PCB 102. The PCB 102 is shown with two fastening systems 112 (e.g., fastening system 200 of FIGS. 2A and 2B, or fastening system 300 of FIGS. 3A and 3B), including a first fastening system 112a and a second fastening system 112b, installed (e.g., soldered or welded) thereon. The fastening systems 112 may mechanically couple one or more components to the other side of the PCB 102 (e.g., second side 120 of FIG. 1). For example, a single component may receive both fasteners 104 of the fastening systems 112. In another example, each fastening system 112 may mechanically couple a separate component to the PCB 102. As described above, in place of the PCB 102 may be a metal plate or other suitable part able to be soldered or welded to the mounting holders 114 and having through-holes adapted to receive the fasteners 104.

During visual inspection, the first fastening system 112a and the second fastening system 112b may be identified as fastened and unfastened, respectively. For example, due to the destructible film 802a being destructed and the fastener 104 (e.g., fastener 204 of FIGS. 2A-3B and 5A-7) being visible in the first fastening system 112a, it may be concluded that a fastening tool was applied to destruct (e.g., puncture, break, sever, collapse, fracture, crack, split, etc.) the destructible film 802a and permit the fastening tool into the fastening system 112a. In contrast, the second destructible film 802b may cover the opening through which the fastening tool extends during fastening (e.g., opening 240 or opening 340). Thus, it may be concluded that a fastening tool has not been applied and therefore the second fastening system 112b is in the unfastened state.

In this way, the destructible films 802 may be visually examined to determine whether the fasteners 104 have been fastened prior to incorporation of the PCB 102 into an assembly, such as an inverter, electric machine, or other electrical system of a vehicle (e.g., electrical system 101 of FIG. 1). Therefore, instances of neglecting to fasten the fastener 104 in a manual assembly line may be reduced.

Combinations of aspects of the fastening system examples provided herein (e.g., fastening system 200 and fastening system 300) are possible without departing from the scope of the present disclosure. For example, a PTH mounting holder may include a cylindrical metal case and leads protruding therefrom. For another example, an SMD mounting holder may include a flat destructible film (e.g., destructible film 702 of FIG. 7). As yet another example, a PTH mounting holder may include a conforming destructible film (e.g., destructible film 318 of FIGS. 3A and 3B). Fastening systems in accordance with the present disclosure, including the examples shown and variations thereof, may be utilized in assembly of systems including a PCB and a component mechanically coupled to the PCB.

For example, turning to FIG. 4, a method 400 for assembling a PCB system with fastening systems in accordance with the present disclosure is shown as a flowchart. For example, the PCB system 100 of FIG. 1 may be manufactured by implementing the method 400. The method 400 may be carried out at least in part by an automated machine. In some examples, some of the steps of the method 400 may be performed manually.

The method 400 begins at 402, wherein a fastening system (e.g., fastening system 112 of FIG. 1, fastening system 200 of FIGS. 2A and 2B, or fastening system 300 of FIGS. 3A and 3B) is installed onto a PCB (e.g., PCB 102 of FIG. 1). The fastening system includes a mounting holder (e.g., mounting holder 114 of FIG. 1, mounting holder 202 of FIGS. 2A and 2B or mounting holder 302 of FIGS. 3A and 3B) and a fastener (e.g., fastener 104 of FIG. 1, fastener 204 of FIGS. 2A-3B) held within the mounting holder by a retaining washer (e.g., retaining washer 208 of FIGS. 2A and 2B or retaining washer 308 of FIGS. 3A and 3B). For example, the PCB and the mounting holder may be obtained by manufacturing with an automated machine. The PCB may include conductive traces (e.g., copper traces) between pads and/or through-holes configured to be soldered or welded to PTH and/or SMD components, respectively. Installing the fastening system onto the PCB may include mechanically coupling (e.g., soldering or welding) the mounting holder to plated pads or through-holes of the PCB for SMD mounting holders (e.g., mounting holder 202 of FIGS. 2A and 2B) or PTH mounting holders (e.g., mounting holder 302 of FIGS. 3A and 3B), respectively.

As such, installing the holder at 402 includes 404, wherein the mounting holder is automatically positioned. For example, the mounting holder may be automatically positioned by the same automated machine that produces the PCB prior to 402. In this way, manual positioning of the fastener may not be demanded, reducing occurrence of interchanging fastener types and misalignment due to human errors. Specifically, the mounting holder may be positioned such that the fastener encased by the mounting holder is in alignment with a corresponding hole in a component adapted to receive the fastener.

Installing the mounting holder at 402 further includes 406, wherein the mounting holder is automatically soldered to a first side of the PCB. For example, the automated machine, or another automatically operated machine in a mechanical assembly line, may solder the metal case of the mounting holder to the PCB in the pre-positioned location of 404 (e.g., pad or through-hole of the PCB). For example, soldering of the mounting holder may occur concurrently with automated soldering of electrical components (e.g., resistors, capacitors, etc.) to the PCB.

The method 400 proceeds to 408, wherein the mounting holder is aligned with a corresponding hole of a component (e.g., corresponding hole 110 of FIG. 1) on a second side of the PCB. The second side of the PCB may be opposite of the first side of the PCB to which the mounting holder is soldered or welded at 406. The corresponding hole may be adapted to receive and be secured with the fastener. For examples where the fastener is a screw, the corresponding hole may be a blind hole or through-hole with complementary threading to the screw such that the corresponding hole is adapted to receive and be tightened with the screw. Aligning the mounting holder with the corresponding hole may include moving the PCB with the fastening system coupled thereto with respect to the component, and/or moving the component with respect the PCB and the fastening system coupled thereto.

The method 400 proceeds to 410, wherein the fastener is fastened into the corresponding hole by applying a fastening tool. In this way, the fastener may couple the PCB and the component comprising the corresponding hole. The PCB may be interposed between the holder and the component, with force applied by the fastening tool securing the PCB, the fastener, and the component to each other. The fastening tool may drive the fastener automatically or manually.

Fastening the fastener at 410 includes 412, wherein a destructible film (e.g., destructible film 702 of FIG. 7, destructible film 318 of FIGS. 3A and 3B, destructible film 802 of FIG. 8) of the mounting holder is destructed. Application of the fastening tool may destruct the destructible film. For example, the fastening tool may apply pressure to the destructible film prior to contacting the faster, destructing (e.g., puncturing or otherwise breaking) the destructible film. In this way, the destructible film may visually indicate whether the fastener has been fastened, whether or not the fastener is visible through the mounting holder. For example, an intact destructible film may indicate the fastening tool has yet to be applied, and thus the fastener is unfastened. Likewise, a destructed destructible film may indicate the fastening tool has been applied, and this the fastener is tightened. The destructible film may be a bright color, for example, to increase visual impact of differences between the destructed and intact states of the destructible film, and therefore increase ease and accuracy of determining a state of the fastening system (e.g., fastened or unfastened).

Fastening the fastener at 410 further includes 414, wherein the fastening tool is guided via the mounting holder. The tool may be inserted into an opening in the metal case underneath the destructible film. For example, the opening through which the fastener extends into the metal case may be sized and shaped to slide against the fastening tool, guiding the orientation of the fastening tool during fastening. For example, the metal case of the mounting holder may be shaped so as to guide the fastening tool in a direction that is perpendicular with the PCB, and parallel with the fastener and the corresponding hole. In this way, whether the fastener is tightened automatically or manually, slippage of the fastener or tool may be avoided, reducing degradation of parts and assembly time.

Fastening the fastener at 410 further includes 416, wherein the fastener is released from the retaining washer. For example, pressure applied to the fastener by the fastening tool may overcome holding forces (e.g., friction, compression, etc.) that retain the fastener to separate the fastener from the retaining washer. After being released, the fastener may not be circumferentially surrounded by the retaining washer. The fastener may then be driven further into the corresponding hole to secure the PCB to the component.

The method 400 ends after 410. After completing the method 400, the fastener may securely attach the PCB and the component. By implementing the method 400, steps of assembly conventionally performed manually, such as positioning and guiding the fastener, may be automated, decreasing assembly time. Further, slipping of the fastener and fastening tool may be reduced due to guiding the fastening tool, decreasing degradation and further lessening assembly time.

Turning to FIGS. 5A-5D, the fastening system 200 is shown at different points in an assembly process, such as at different steps in the method 400 of FIG. 4. The fastening system 200 may prevent manual errors (e.g., misalignment, slipping, degradation to components, interchanging types of fasteners, etc.) during alignment and fastening of the fastener 104 to secure a component 504 to a PCB 502. The component 504 is shown as a spacer configured to space the PCB 502 from a second PCB 506 at a fixed distance (e.g., length of the spacer). The PCB 502 and the second PCB 506 may be incorporated into an electrical system of a vehicle (e.g., electrical system 101 of FIG. 1). However, the fastening system 200 may be used to fasten other components than spacers to a PCB. A first view 510 is shown in FIG. 5A, a second view 520 is shown in FIG. 5B, a third view 530 is shown in FIG. 5C, and a fourth view 540 is shown in FIG. 5D.

The first view 510 shows the fastening system 200 in an unfastened state, where the mounting holder 202 is soldered to a first side 514 of the PCB 502 and the fastener 204 is not in contact with the component 504. For example, the view 510 may show the fastening system 200 after step 408 and before step 410 of the method 400 in FIG. 4. The leads 214 may extend through plated lead holes 522 in the PCB 502. In this way, the leads 214 may be soldered or welded to the plated lead holes 522 via PTH soldering or welding. The fastener 204 may extend partially into a through-hole 518 in the PCB 502. In this way, the fastener 204 may be pre-positioned prior to fastening, reducing occurrence of errors such as interchanging fastener types and misaligning the fastener 204 with the through-hole 518, and decreasing assembly time. The component 504 may be vertically aligned with the fastener 204 and located on a second side 516 of the PCB 502 such that the PCB 502 is interposed between the mounting holder 202 and the component 504.

The second view 520 shows the fastening system 200 during fastening, with a fastening tool 508 applying pressure to the fastening system 200 in a direction indicated by arrow 512. For example, the second view 520 may show the fastening system 200 during step 410, prior to steps 414 and 416, of method 400 in FIG. 4. Though not shown in FIGS. 5A-5D, the mounting holder 202 may include a destructible film. Upon application of the fastening tool 508, the destructible film may be destructed. A destructed film may be a visual indication that the fastener 204 is fastened to the PCB 502 and the component 504, increasing quality of assembly by providing visual assurance that each fastener of the assembly is tightened. The fastener 204 may remain retained by the retaining washer 208 while the destructible film is destructed. For example, the fastener 204 may be in the same position relative to the mounting holder 202 and the PCB 502 in the views 510 and 520. The fastening tool 508 may not be guided by the mounting holder 202 in the stage shown in the second view 520 due to the tapered end of the fastening tool 508 being spaced away from edges defining the opening 240.

The third view 530 shows the fastening system 200 at a later phase of fastening where the fastener 204 is released from the retaining washer 208 and the fastening tool 508 is guided by the mounting holder 202. For example, the third view 530 may show the fastening system 200 during step 410 and after step 416 of method 400 in FIG. 4. The fastener 204 may extend further through the through-hole 518 in the third view 530 than the first view 510 and the second view 520. Consequently, the head bottom 244 may be located closer to the PCB 502 in the third view 530 than in the first view 510 and the second view 520. Additionally, the fastener 204 may be spaced away from the retaining washer 208. The opening 240 may permit the fastening tool 508 to enter the metal case 206 in order to fasten the fastener 204 by driving the fastener 204 down, in the direction indicated by the arrow 512. During fastening, the fastening tool 508 may continue to apply pressure to the fastener 204 in the downward direction indicated by the arrow 512 that is parallel with the fastener 204 and the corresponding hole in the component 504. For examples where the fastener 204 is a screw, the fastening tool 508 may rotate while applying pressure to tighten the screw into the through-hole of the PCB 502 and corresponding threaded hole of the component 504. The edges defining the opening 240 may circumferentially surround and be in face sharing contact with the fastening tool 508. In this way, the fastening tool 508 may be guided in a direction that is perpendicular to the PCB 502 and parallel with the fastener 204. Due to the size and shape of the opening 240 matching the size and shape of the fastening tool 508 such that the metal case 206 wraps around the fastening tool 508 during fastening, the metal case 206 may support the fastening tool 508 so as to prevent slipping or misalignment thereof. In this way, degradation of parts during assembly may be reduced, as well as assembly time.

The fourth view 540 shows the fastening system 200 in a fastened position, where the fastener is secured to the PCB 502 and the component 504. For example, the fourth view 540 may show the fastening system 200 following completion of the method 400 of FIG. 4. For example, the head bottom 244 of the fastener 204 may be flush with the PCB 502. The body of the fastener 204 may extend through the through-hole 518 in the PCB 502 and into the corresponding hole in the component 504. In this way, the fastener 204 may hold the component 504 to the PCB 502. The mounting holder 202 may remain in the same position prior, during, and following fastening, due to being soldered or welded to the PCB 502. In examples where the metal case 206 is coated in an electrically insulating material, the metal case 206 may provide electrical insulation between the fastener 204 and electrical components, reducing interference of the fastener 204 with functions of such electrical components. In at least some examples, the fastener 204 may be removable from the component 504, such as examples where the fastener 204 is a screw. Therefore, the fastener 204 may be unscrewed out of the corresponding hole in the component 504, releasing the component 504 from the PCB 502, which may be useful for performing maintenance, for instance. The fastener 204 may remain at least partially within the PCB 502 such that the fastener 204 remains in the correct position (e.g., aligned with the through-hole in the PCB 502), and the fastening tool 508 may be reinserted into the metal case 206 to guide the fastener back into the component 504, when recoupling is demanded, for example following maintenance or repair.

In this way, the PTH mounting holder 202 may guide the fastener 204 when under pressure from the fastening tool 508 from the pre-positioned, unfastened state to the fastened state such that misalignment and slipping may be reduced. Similarly, an SMD mounting holder may be used for the same effect of reducing likelihood of misalignment and slipping during tightening of the fastener with the component.

For example, turning to FIGS. 6A-6D, the SMD fastening system 300, including the mounting holder 302, is shown at different points in an assembly process, such as at different steps in the method 400 of FIG. 4. The fastening system 300 may reduce manual errors (e.g., misalignment, slipping, degradation to components, interchanging types of fasteners, etc.) during positioning and fastening of the fastener 204 to secure the component 504 to a PCB 602. The PCB 602 may not include the lead holes 514 of FIGS. 5A-5D. Instead, the PCB 602 may include plated pads 604 that are conducive to soldering or welding to the metal case 306. A first view 610 is shown in FIG. 6A, a second view 620 is shown in FIG. 6B, a third view 630 is shown in FIG. 6C, and a fourth view 640 is shown in FIG. 6D.

The first view 610 shows the fastening system 300 in an unfastened state where the fastener 204 is retained by the retaining washer 308 and not coupled to the component 504. For example, the first view 610 may show the fastening system 300 between step 408 and step 410 of the method 400 in FIG. 4. Though not shown, the fastening system 300 may include a destructible film (e.g., destructible film 802 of FIG. 8, flat destructible film 702 of FIG. 7, conforming destructible film 318 of FIGS. 3A and 3B), which is intact (e.g., not destructed) in the unfastened state. The fastening system 300 may be pre-positioned with the fastener 204 in alignment with through-hole 612 in the PCB 602. The metal case 306 may be soldered or welded to the plated pads 604 on a first side 614 of the PCB 602 such that the metal case 306 is mechanically and permanently coupled to the PCB 602. Thus, the metal case may remain in the same position preceding, during, and following fastening of the fastener 204 by driving the fastener 204 down with the fastening tool 508. Soldering or welding of the metal case 306 to the PCB 602 may occur automatically via an automated machine. The fastener 204 may extend partially into the through-hole 612 prior to fastening (e.g., by the distance 706 of FIG. 7). In this way, automatic alignment of the fastener 204 with the through-hole 612 may reduce slipping and degradation during fastening. Further, selection and alignment of appropriate fastener types may be removed from manual assembly lines, reducing instances of interchanging fastener types and misaligning the fasteners. Further still, pre-positioning the fastening system 300 on a side of the PCB may designate orientation of the component 504 being on a second side 616 opposite of the first side 614, preventing inversion during assembly.

The second view 620 shows the fastening system 300 during fastening, with the fastening tool 508 applied to the fastening system 300. For example, the second view 620 may show the fastening system 300 after step 412 and before step 414 of the method 400 of FIG. 4. Application of the fastening tool 508 may destruct the destructible film, in examples where a destructible film is included in the fastening system 300. The fastening tool 508 may apply pressure to the fastener 204 in the direction indicated by the arrow 512, perpendicular to the PCB 602. Due to the tapered end of the fastening tool 508 being smaller than the opening 340, the metal case 306 may not be in face sharing contact with the fastening tool 508 in the second view 620. Therefore, the fastening tool 508 may not be guided by the metal case 306 at this point during fastening.

The third view 630 shows the fastening system 300 during a later phase of fastening after the pressure applied by the fastening tool 508 releases the fastener 204 from the retaining washer 308, and the fastening tool 508 is guided by the opening 340. For example, the third view 630 may show the fastening system 300 during step 410, and after step 416, of method 400 in FIG. 4. Once released from the retaining washer 308, the fastener 204 may move down toward the component 504, under pressure from the fastening tool 508 in the direction indicated by the arrow 512. The fastener 204 may be spaced away from the retaining washer 308 after being released. The fastener 204 may extend fully through the through-hole 612 and partially into the corresponding hole 606 in the component 504. The head bottom 244 may be spaced away from the PCB 602 in the view 630, and thus fastening may not be concluded. The fastening tool 508 extending through the opening 240 in face sharing contact with the metal case may stabilize the fastening tool 508 during fastening such that slipping and resulting degradation is reduced. After fastening, the fastening tool 508 may be withdrawn from the metal case 306 by sliding upwards out of the opening 340 (e.g., in a direction opposite that of the arrow 512).

The fourth view 640 shows the fastening system 300 in a fastened state where the fastener secures the component 504 and the PCB 602 together. For example, the fourth view 640 may show the fastening system 300 following completion of the method 400 of FIG. 4. The mounting holder 302 remains intact in the fastened state due to being soldered to the PCB prior to fastening. In examples where the mounting holder 302 is coated in an electrically insulating material, the mounting holder 302 may electrically insulate the fastener 204 from electrically conductive components during use of the PCB 602 in an electrical system (e.g., of a vehicle), such as an inverter or electric machine of a vehicle. The fastening system 300 may be in the fastened state when the fastener 204 securely mechanically couples the component 504 with the PCB 602, for example when the head bottom 244 is in face sharing contact with the PCB 602 as shown in the fourth view 540. A destructed destructible film, in applicable examples, may indicate the fastening tool 508 has been inserted through the opening 340, and thus that fastening may have occurred. As described above, the fastener 204 may be removable from the component 504, and may be subsequently recoupled with the component 504.

The technical effect of the mounting holders of the fastening systems disclosed herein is to position a fastener in alignment with a through-hole in a PCB and to guide the fastener and a fastening tool during fastening of the fastener with the PCB and a component such that misalignment, slipping, falling, or other degradation causing events are reduced (e.g., prevented). Positioning may be performed automatically by soldering or welding the mounting holder to the PCB via SMD or PTH technology, reducing errors occurring in manual assembly lines, such as interchanging fastener types. Automatic positioning may reduce the time used to fasten the fasteners, increasing temporal efficiency of assembly. Additionally, in conventional assembly lines not utilizing mounting holders in accordance with the present disclosure, one or more of the fasteners in a system may be overlooked and thus remain unfastened, resulting in a decrease in stability or lack of mechanical coupling between the PCB and the components. The mounting holders of the present disclosure may address the issue of neglecting to fasten all fasteners by including a destructible film which covers an opening through which the fastening tool is inserted into the metal case, destructing the film upon application of the fastening tool. In this way, the destructible films may be optical assurance that the fastening tool has been applied to each fastening system in an assembly, and therefore that the fasteners may all be fastened.

The disclosure also provides support for a fastening system, comprising: a fastener, a metal case surrounding the fastener and adapted to be soldered or welded to a printed circuit board (PCB), where a top of the metal case has an opening adapted to permit a fastening tool to drive the fastener down, a retaining washer adapted to retain the fastener within the metal case prior to an application of the fastening tool, and a destructible film positioned on the top of the metal case. In a first example of the system, the metal case is soldered or welded to the PCB via plating through-hole (PTH) technology. In a second example of the system, optionally including the first example, the metal case is soldered or welded to the PCB via surface mounted device (SMD) technology. In a third example of the system, optionally including one or both of the first and second examples, the metal case is coated with an electrically insulating material. In a fourth example of the system, optionally including one or more or each of the first through third examples, the retaining washer is co-molded with the metal case. In a fifth example of the system, optionally including one or more or each of the first through fourth examples, the retaining washer is embedded into the metal case. In a sixth example of the system, optionally including one or more or each of the first through fifth examples, the fastener is a screw and the fastening tool is a screwdriver. In a seventh example of the system, optionally including one or more or each of the first through sixth examples, the fastener fastens a spacer to the PCB, and the spacer spaces the PCB from a second PCB at a fixed distance, and wherein the fastening system, the spacer, the PCB, and the second PCB form a PCB system that is incorporated into an electrical system of a vehicle. In a eighth example of the system, optionally including one or more or each of the first through seventh examples, the destructible film is constructed of paper material.

The disclosure also provides support for a method, comprising: installing a fastening system onto a printed circuit board (PCB), the fastening system including a mounting holder and a fastener held within a metal case of the mounting holder by a retaining washer, aligning the mounting holder with a component having a corresponding hole adapted to receive the fastener, and fastening the fastener into the corresponding hole by applying a fastening tool. In a first example of the method, applying the fastening tool destructs a destructible film of the mounting holder and releases the fastener from the retaining washer. In a second example of the method, optionally including the first example the fastening system, and the component form a PCB system that is incorporated into an electrical system of a vehicle following fastening. In a third example of the method, optionally including one or both of the first and second examples, fastening includes guiding the fastening tool via the mounting holder. In a fourth example of the method, optionally including one or more or each of the first through third examples, installing includes positioning the fastening system with the fastener in alignment with a through-hole in the PCB. In a fifth example of the method, optionally including one or more or each of the first through fourth examples, installing further includes soldering or welding the mounting holder to the PCB. In a sixth example of the method, optionally including one or more or each of the first through fifth examples, installing is performed automatically by an automated machine and fastening is performed manually. In a seventh example of the method, optionally including one or more or each of the first through sixth examples, the mounting holder is installed on a first side of the PCB and the component is located on a second side of the PCB opposite the first side, and wherein the component is a spacer that spaces the PCB from a second PCB in an electrical system of a vehicle.

The disclosure also provides support for an assembly, comprising: a printed circuit board (PCB), a fastening system including a mounting holder surrounding a fastener, the mounting holder soldered or welded to a first side of the PCB, and a component secured to a second side of the PCB via the fastener such that the PCB is interposed between the component and the mounting holder, wherein a destructible film of the mounting holder is destructed. In a first example of the system, the fastener extends through a through-hole in the PCB and into a corresponding hole in the component. In a second example of the system, optionally including the first example, the component is a spacer that spaces the PCB from a second PCB in an electrical system of a vehicle.

FIGS. 1 and 8 show schematics of an example configuration with relative positioning of the various components. FIGS. 2A-3B and 5A-7 are shown approximately to scale; though other relative dimensions may be used. As used herein, the terms “approximately” is construed to mean plus or minus five percent of the range unless otherwise specified.

If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Further, elements shown intersecting one another may be referred to as intersecting elements or intersecting one another, in at least one example. Further still, an element shown within another element or shown outside of another element may be referred as such, in one example. Moreover, the components may be described as they relate to reference axes included in the drawings.

Features described as axial may be approximately parallel with an axis referenced unless otherwise specified. Features described as counter-axial may be approximately perpendicular to the axis referenced unless otherwise specified. Features described as radial may circumferentially surround or extend outward from an axis, such as the axis referenced, or a component or feature described prior as being radial to a referenced axis, unless otherwise specified.

Features described as longitudinal may be approximately parallel with an axis that is longitudinal. A lateral axis may be normal to a longitudinal axis and a vertical axis. Features described as lateral may be approximately parallel with the lateral axis. A vertical axis may be normal to a lateral axis and a longitudinal axis. Features described as vertical may be approximately parallel with a vertical axis.

It will be appreciated that the configurations and routines disclosed herein are exemplary in nature, and that these specific embodiments are not to be considered in a limiting sense, because numerous variations are possible. Moreover, unless explicitly stated to the contrary, the terms “first,” “second,” “third,” and the like are not intended to denote any order, position, quantity, or importance, but rather are used merely as labels to distinguish one element from another. The subject matter of the present disclosure includes all novel and non-obvious combinations and sub-combinations of the various systems and configurations, and other features, functions, and/or properties disclosed herein.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A fastening system, comprising:
a fastener;
a metal case surrounding the fastener and adapted to be soldered or welded to a printed circuit board (PCB), where a top of the metal case has an opening adapted to permit a fastening tool to drive the fastener down;
a retaining washer adapted to retain the fastener within the metal case prior to an application of the fastening tool; and
a destructible film positioned on the top of the metal case.

2. The fastening system of claim 1, wherein the metal case is soldered or welded to the PCB via plating through-hole (PTH) technology.

3. The fastening system of claim 1, wherein the metal case is soldered or welded to the PCB via surface mounted device (SMD) technology.

4. The fastening system of claim 1, wherein the metal case is coated with an electrically insulating material.

5. The fastening system of claim 1, wherein the retaining washer is co-molded with the metal case.

6. The fastening system of claim 1, wherein the retaining washer is embedded into the metal case.

7. The fastening system of claim 1, wherein the fastener is a screw and the fastening tool is a screwdriver.

8. The fastening system of claim 1, wherein the fastener fastens a spacer to the PCB, and the spacer spaces the PCB from a second PCB at a fixed distance, and wherein the fastening system, the spacer, the PCB, and the second PCB form a PCB system that is incorporated into an electrical system of a vehicle.

9. The fastening system of claim 1, wherein the destructible film is constructed of paper material.

10. A method, comprising:
installing a fastening system onto a printed circuit board (PCB), the fastening system including a mounting holder and a fastener held within a metal case of the mounting holder by a retaining washer;
aligning the mounting holder with a component having a corresponding hole adapted to receive the fastener; and
fastening the fastener into the corresponding hole by applying a fastening tool.

11. The method of claim 10, wherein applying the fastening tool destructs a destructible film of the mounting holder and releases the fastener from the retaining washer.

12. The method of claim 10, wherein the PCB, the fastening system, and the component form a PCB system that is incorporated into an electrical system of a vehicle following fastening.

13. The method of claim 10, wherein fastening includes guiding the fastening tool via the mounting holder.

14. The method of claim 10, wherein installing includes positioning the fastening system with the fastener in alignment with a through-hole in the PCB.

15. The method of claim 14, wherein installing further includes soldering or welding the mounting holder to the PCB.

16. The method of claim 10, wherein installing is performed automatically by an automated machine and fastening is performed manually.

17. The method of claim 10, wherein the mounting holder is installed on a first side of the PCB and the component is located on a second side of the PCB opposite the first side, and wherein the component is a spacer that spaces the PCB from a second PCB in an electrical system of a vehicle.

18. An assembly, comprising:
a printed circuit board (PCB);
a fastening system including a mounting holder surrounding a fastener, the mounting holder soldered or welded to a first side of the PCB; and
a component secured to a second side of the PCB via the fastener such that the PCB is interposed between the component and the mounting holder, wherein a destructible film of the mounting holder is destructed.

19. The assembly of claim 18, wherein the fastener extends through a through-hole in the PCB and into a corresponding hole in the component.

20. The assembly of claim 18, wherein the component is a spacer that spaces the PCB from a second PCB in an electrical system of a vehicle.
